(19) United States
(12) Patent Application Publication
(10) Pub. No.: US 2008/0075575 A1
(43) Pub. Date: Mar. 27, 2008

(54) TRAY CARRIER AND SYSTEM INCLUDING THE TRAY CARRIER FOR HANDLING AND TRANSPORTING SEMICONDUCTOR PACKAGES

(75) Inventors: Jae-nam LEE, Cheonan-si (KR); Eduard KURGI, Suwon-si (KR); Hee-jin KIM, Suwon-si (KR); Jung-hyeon KIM, Hwaseong-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/844,364

(22) Filed: Aug. 24, 2007

(30) Foreign Application Priority Data
Sep. 27, 2006 (KR) 10-2006-0094331

(51) Int. Cl. H01L 21/673

(52) U.S. Cl. 414/787

(57) ABSTRACT

A system for facilitating the handling and transporting of semiconductor packages includes a stock of trays in which semiconductor packages can be held, and a tray carrier by which a stack of the trays can be easily handled using automated equipment and without producing dust. The tray carrier includes a frame having an open bottom end through which a stack of trays can be inserted into the frame, belt drums mounted on both sides of the bottom end of the frame, fork blocks mounted to the frame under the belt drums, and a belt extending from the belt drums through the fork blocks and across the open bottom end of the frame. When the tray carrier is placed over a stack of the trays, the belt surrounds the top and sides of the stack of trays. The fork blocks include prongs that are movable into the space constituting the open bottom end of the frame so as to support the bottom of the stack of trays. The tray carrier also has fork handles for actuating the fork blocks, and locking handles for locking the fork blocks in place.

### BACKGROUND OF THE INVENTION

1. Field of the Invention

The present invention relates to the handling and transport of semiconductor devices. More particularly, the present invention relates to a tray carrier for handling and transporting trays in which semiconductor packages are stored.

2. Description of the Related Art

Semiconductor packages are generally handled and transferred in lots. More specifically, lots of semiconductor packages are carried to stations at which electrical testing of the packages and assembly processes take place. To this end, a tray is used to facilitate the handling and transport of the semiconductor packages. That is, the semiconductor packages are first loaded onto trays and the trays are carried to the stations at which the packages are tested and assembled to external devices.

The tray also protects the semiconductor packages from external shock during their handling and transport. Such trays have been standardized according to international standards set by the Joint Electron Device Engineering Council (JEDEC), and have pockets configured to accommodate a plurality of semiconductor packages. In general, several of the trays are stacked and carried together to the stations at which electrical testing and assembly processes take place. FIG. 1 shows a conventional carrier 12 used to carry a stack of trays in which semiconductor packages are held.

The carrier 12 includes a band of fabric, and a fastener, e.g., Velcro, attached to the band. Two of the carriers 12 are secured around a stack of trays 10. In addition, a lot information card 14 is inserted between the uppermost tray 10 of the stack and the tray carrier 12 to help an operator identify the semiconductor packages held by the trays 10.

The conventional tray carriers 12 are inexpensive, compact and can be handled easily by an operator. In addition, the conventional tray carriers 12 can bundle the trays 10 regardless of the number of trays 10 to be handled and transported. However, the conventional tray carriers 12 have some drawbacks.

The banding/unbanding process, i.e., the bundling and unbundling of the trays using the carriers 12, must be performed manually. That is, it is difficult to automate the banding/unbanding process because the Velcro fasteners and the use of several carriers 12 for each bundle of trays 10 does not lend itself to automated handling equipment. Thus, the conventional carriers 12 are an obstacle to automating the entire manufacturing, test and assembly lines.

In addition, the operator must lift, rotate, or move the heavy bundle of the trays during the banding/unbanding process. Such manual work is difficult for the operator, and requires a great amount of time. In addition, the work is cumbersome because the conventional tray carrier 12 is difficult to grip when it is secured around a stack of trays 10.

Also, semiconductor devices generally must be manufactured in a high purity environment, i.e., an environment that is substantially free of impurities and dust (particles). However, the conventional tray carrier can produce particles when the Velcro fastener is attached/detached. Therefore, the conventional tray carrier is not suitable for use in an environment in which semiconductor devices are being manufactured.

In addition, despite the effectiveness of the conventional tray carriers 12 in securing the trays 10 to one another, transporting the stacks of the trays often requires placing the secured stacks of trays in carrier boxes (not shown). In addition, the stacks of trays 10 can vary in height depending on the number of semiconductor packages that make up a particular lot. Accordingly, a variety of carrier boxes of different sizes are often required to best handle and transport the stacks of trays in a semiconductor device manufacturing facility. That is, a variety of separate carrier boxes have to be stored in the facility.

### SUMMARY OF THE INVENTION

An object of the present invention is to provide a tray carrier which is easy to manipulate and operate. A related object of the present invention is to provide a system that makes it easy to handle and transport semiconductor devices.

Another object of the present invention is to provide a tray carrier which can be employed by automated manufacturing equipment. Similarly, an object of the present invention is to provide a system by which semiconductor devices can be handled and transported using automated equipment.

Still another object of the present invention is to provide a tray carrier which will not produce dust while in use. Similarly, an object of the present invention is to provide a system for facilitating the handling and transporting of semiconductor devices, which will not produce dust.

According to one aspect of the present invention, there is provided a tray carrier which includes a frame having an open bottom end, at least one resilient belt of material mounted to the frame and spanning the open bottom end of the frame, and at least one pair of fork blocks disposed at opposite sides of the bottom end of the frame. Preferably, the belt is formed of rubber, i.e., a material that does not produce dust. Each of the fork blocks has a fixed fork block body that is fixed to the frame, and a movable fork member that includes a prong. The movable fork member is supported by the fixed block body so as to be movable between a first position at which the prong extends into the space constituting the open bottom end of the frame and a second position at which the prong is located outside said space. Thus, when the tray carrier is set on top of a stack of trays, the belt surrounds the top and sides of the stack of trays, and the prongs of the fork blocks can be inserted under the stack of trays.

The tray carrier also has at least one pair of belt drums mounted to the frame. The belt drums are disposed across from one another at the opposite sides of the bottom end of the frame, and the belt is wound around the belt drums. Each of the belt drums includes a rotatable hub to which the belt is connected, and a spring connected to the hub so as to bias the hub in one direction of rotation. The springs of the belt drums bias the hubs in opposite directions of rotation of the hubs such that the belt is tensioned by and supported between the belt drums.

Preferably, the frame includes a first rigid frame unit, a second rigid frame unit spaced from the first rigid frame unit, and at least one handle extending between and connecting the frame units. The tray carrier also has a locking mechanism by which the movable fork member of each of the fork blocks can be selectively locked in the first and second positions thereof, a fork block handle connected to the movable fork member of each of the fork blocks, and a locking handle connected to the locking mechanism. The fork block handle is linearly movable back and forth to move the movable fork member between the first and second positions thereof. The locking handle can be pressed to release the locking mechanism.

Also, the fixed fork block body and the movable fork member of each of the fork blocks define a passageway therebetween. The belt extends through the passageway in the fork block from the belt drum that is disposed over the fork block. The width of the passageway is less than the thickness of the belt when the movable fork member is in the first position thereof, and the width of the passageway is greater than the thickness of the belt when the movable fork member is at the second position thereof. Therefore, the belt is clamped between the fixed fork body and the movable fork member in the passageway when the movable fork member is at the first position thereof, and the belt is free to slide through the passageway when the movable fork member is at the second position thereof.

The tray carrier may also have a cover integrated with the belt. The cover is sized to fit on and cover the uppermost tray in the stack on top of which the tray carrier is placed.

According to another aspect of the present invention, there is provided a system for facilitating the handling and transporting of semiconductor devices, wherein the system includes the combination of a stock of trays that are stackable one atop the other, and a tray carrier having features as summarized above. The trays have pockets in upper surfaces thereof, and the pockets are configured to accommodate semiconductor devices. In the case in which a tray cover is integrated with the belt, the cover and the trays may be of the same material.

### BRIEF DESCRIPTION OF THE DRAWINGS

The above and other objects, features and advantages of the present invention will become more apparent inform the following detailed description of the preferred embodiments thereof made with reference to the attached drawings in which:

FIG. 1 is a perspective view of stacks of trays and conventional tray carriers for carrying the stacks of trays;

FIG. 2 is a perspective view of a tray carrier according to the present invention;

FIG. 3 is a side view of the tray carrier seen from direction A in FIG. 2;

FIG. 4 is a side view of the tray carrier seen from direction B in FIG. 2;

FIG. 5 is a sectional view of a belt drum of the tray carrier according to the present invention;

FIG. 6 is a perspective view of a pitchfork block of the tray carrier according to the present invention;

FIG. 7 is a cross-sectional view of the pitchfork block taken along VII-VII′ of FIG. 6;

FIG. 8 is a cross-sectional view of the pitchfork block taken along line VIII-VIII′ of FIG. 6; and

FIGS. 9 and 10 are each a cross-sectional view of a bundling mechanism of the tray carrier according to the present invention and together illustrate the bundling/unbundling of a stack of trays.

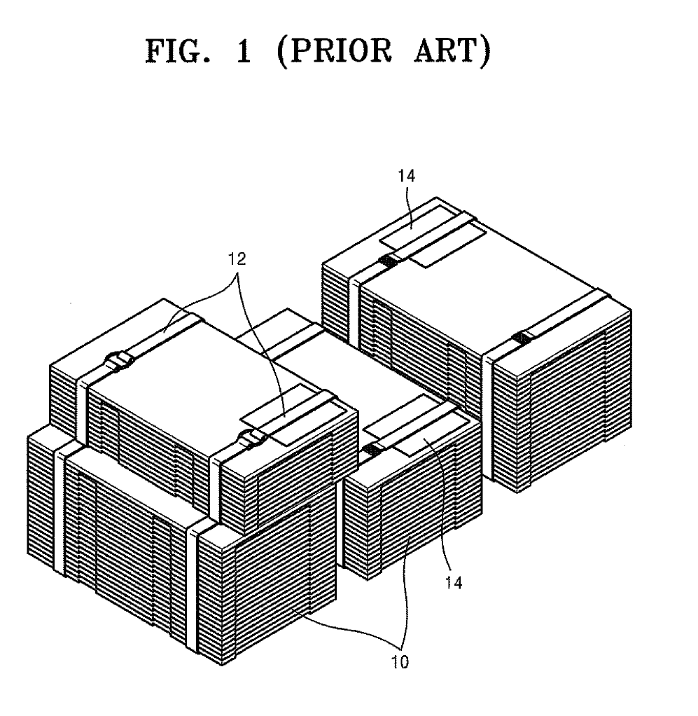

### DETAILED DESCRIPTION OF THE PREFERRED EMBODIMENTS

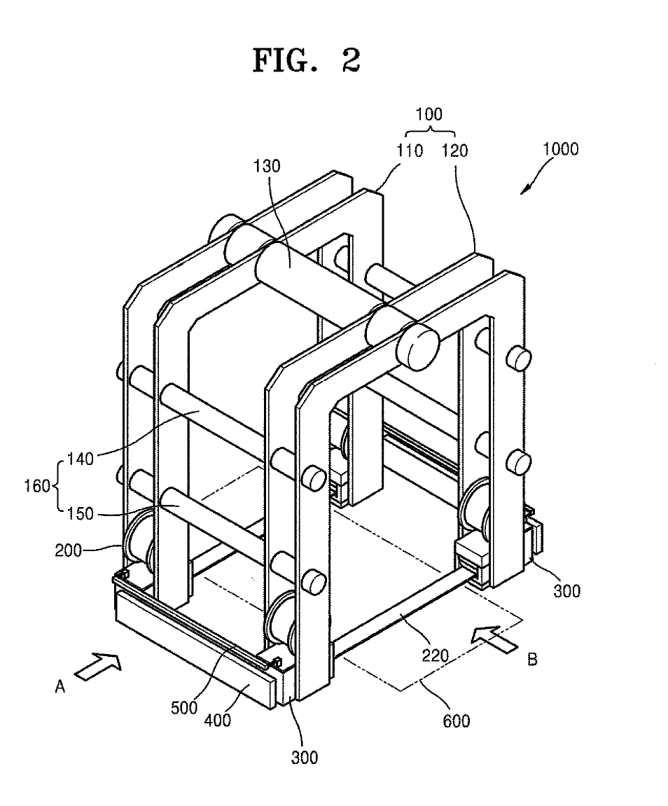

Referring to FIG. 2, a tray carrier 1000 according to the present invention includes a tray carrier frame 100 delimiting a space in which a stack of trays can be placed. Preferably, the frame 100 is formed of a rigid, durable and highly corrosive resistant material. In particular, the frame 100 can be formed of a plastic that prevents an electrostatic discharge (ESD) from occurring or can be formed of a metal such as aluminum. The frame 100 includes a first rigid frame component 110, a second rigid frame component 120 spaced a predetermined distance from the first rigid frame component 110 and having the same structure as that of the first rigid frame component 110, and support members connecting the first and second rigid frame components 110 and 120 to each other.

The support members include a top handle 130 disposed at an upper central portion of the frame 100 so that the tray carrier 1000 can be grasped at the top thereof and can be carried easily. The support members also include side handles 160 including an upper side handle 140 and a lower side handle 150 extending between and connecting each of the respective sides of the first and second rigid frame components 110 and 120 to one another. Thus, the side handles 160 securely fix the first and second rigid frame components 110 and 120 to each other.

As illustrated in FIG. 2, the frame 100 has the shape of an inverted horseshoe so as to be open at the bottom end thereof. However, the present invention is not so limited. Rather, the frame can have other shapes so long as a stack of trays can be accommodated within the frame 100. In addition, the top and side handles 130 and 160 are cylindrical and, in particular, have circular cross sections in the embodiment of FIG. 2. However, the top and side handles 130 and 160 can have other shapes and cross sections.

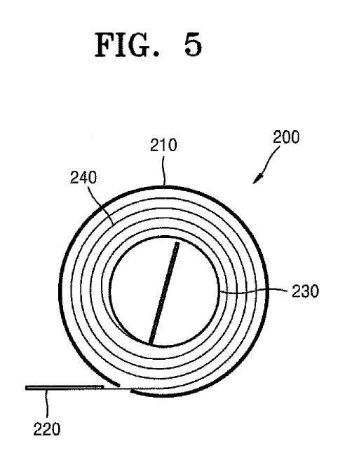

The tray carrier 1000 according to the present invention also includes four belt drums 200 mounted on a lower portion of the frame 100. More specifically, each of the rigid frame units 110 and 120 defines openings at opposite sides of the lower portion thereof. A respective belt drum 200 is disposed in each opening such that a pair of belt drums 200 is mounted to each of the rigid frame units 110 and 120 and the belt drums 200 of each pair oppose each other at opposite sides of the rigid frame unit. In addition, a belt 220 that is used to bind the stack of trays is wound around the belt drums 200 of each pair. The belt 220 may be formed of a material, such as rubber, that will not produce dust particles. The structure of the belt drums 200 will be described in more detail later on with reference to FIG. 5.

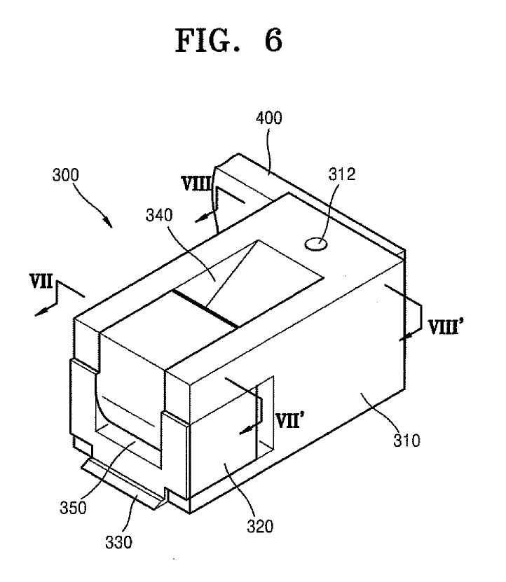

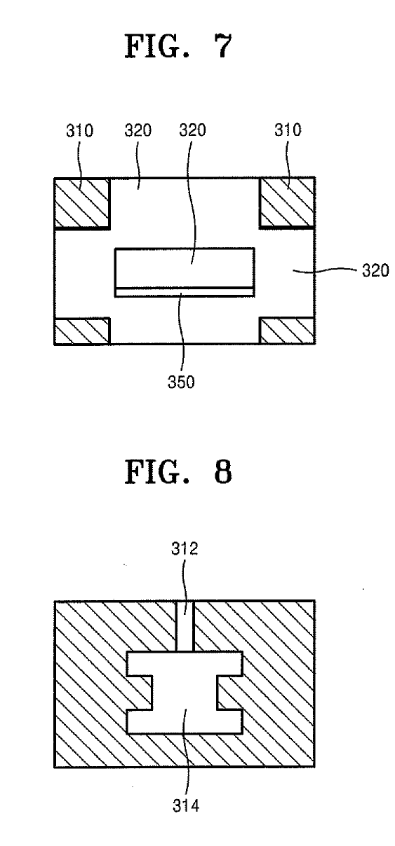

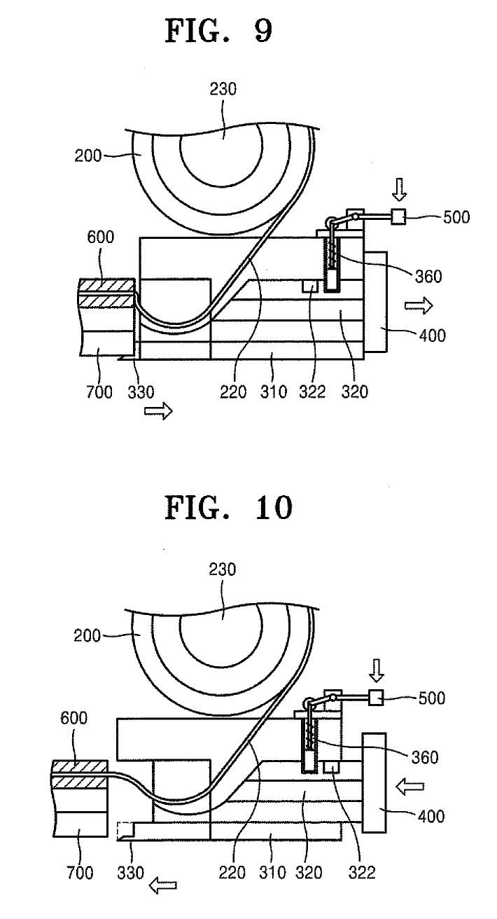

The tray carrier 1000 also includes four fork blocks 300, a pair of fork block handles 400, and a pair of locking handles 500. The fork blocks 300 are disposed under the belt drums 200, respectively. Normally, the belts 220 extend through the fork blocks 300 across the open bottom end of the frame 100. The fork blocks 300 tighten and loosen the belts 220, and support the trays from below. The structure of the fork blocks 300 will be described in more detail later on with reference to FIGS. 6 through 8. The fork block handles 400 are each connected to the fork blocks 300 that are located on the same side of the frame 100, for example, on the side denoted by A in FIG. 2. The fork handles 400 are basically used to insert prongs of the fork blocks 300 below a stack of trays over which the tray carrier 1000 has been placed. Each locking handle 500 is disposed over a respective fork block handle 400 and is operative to lock the fork block handle 400 in place. The operation of the fork blocks 300, fork block handles 400 and locking handles will be described in more detail later on with respect to FIGS. 9 and 10.

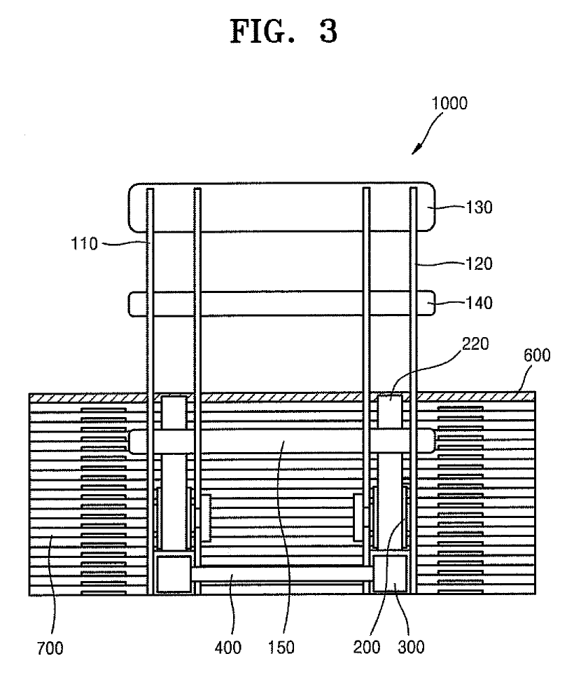

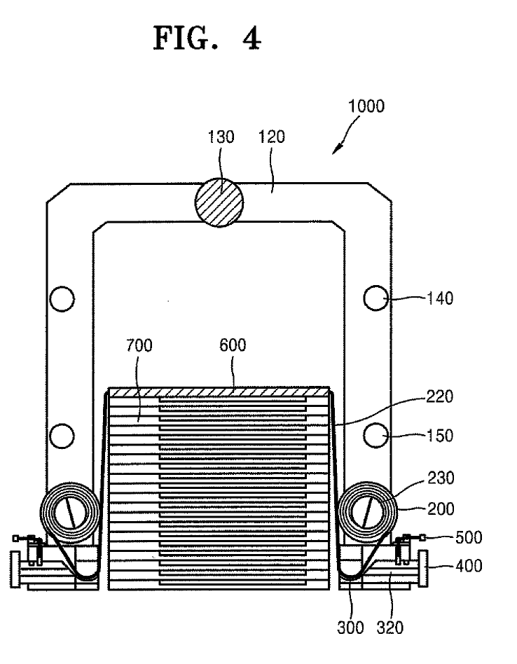

Referring now, though, to FIGS. 3 and 4, a stack of trays 700 is loaded into the tray carrier 1000 by, for example, placing the tray carrier 1000 on top of the stack of trays. At this time, a cover 600 may be provided on the stack of trays 700. The cover 600 may be integrated with the belts 220 that extend across the open bottom end of the frame 100. Therefore, the stack of trays 700 is covered by the cover 600 and the belts 220 while being received in the frame 100 of the tray carrier 1000.

The cover 600 prevents semiconductor packages accommodated in the pockets of the uppermost tray from escaping from the pockets. Therefore, the cover 600 has a structure that can rest stably on a tray, and the cover 600 may be the same size as each of the trays. In addition, the cover 600 should also be of a material that prevents the build up of electrostatic charges, i.e., should have an ESD function, and may be formed of the same material as that of the trays 700.

Referring to FIG. 5, each belt drum 200 has a belt drum main body 210, a central hub 230 disposed at the center of the belt drum main body 210, and a spiral spring 240 attached to the central hub 230. The central hub 230 is mounted to a respective one of the rigid frame components 110a and 120 so as to be rotatable. Each belt 220 is connected to the hubs 230 of an opposing pair of the belt drums 200 (FIG. 4). The spiral spring 240 biases the central hub 230 in one direction of rotation about the central axis of the hub 230. More specifically, the spiral springs 240 of the opposing pair of the belt drums 200 tension the belt 220 to draw the belt 200 around the belt drums 200. Each belt 200 extends from the hubs 230 of an opposing pair of the belt drums 200 through a respective pair of the fork blocks 300 and across the open bottom end of the frame 100.

Referring to FIGS. 6 through 8, each fork block 300 includes a fixed fork block body 310 having a cavity therein, a movable fork member 320 disposed in the cavity of the fork block body 310 so as to be slidable relative to the fork block body 310 in opposite directions towards the front and back of the fork block body 310, and a locking device 360 (see FIG. 9) for locking the movable fork member 320 in place relative to the fork block body 310. The movable fork member 320 has a prong 330 at the bottom of the front end thereof. The thickness of the prong 330 decreases from the rear portion to the front portion thereof, and may come to a point, so that the prong 330 can be easily inserted between a stack of trays and the surface on which the stack of trays is resting. The fixed fork block body 310 and the movable fork member 320 define a passageway therebetween through which the belt extends. The passageway includes an inlet 340 into which the belt 220 extends from the belt drum 220, and an outlet 350 from which the belt 220 extends out of the fork block 300.

The width of the passageway is reduced as the movable fork member 320 is slid toward the front of the fixed fork block body 310. Conversely, the width of the passageway increases as the movable fork member 320 is slid toward the back of the fixed fork block body 310. The fork block handle 400 is integral with the movable fork member 320 so that when the fork block handle 400 is pushed or pulled, the movable fork member 320 is slid toward the front or back of the fixed fork block body 310. Therefore, the belt 220 is clamped or unclamped by operating the fork block handle 400.

The locking mechanism 360 (refer to FIGS. 6, 8 and 9) is mounted to the fork block body 310. The locking mechanism 360 includes a plunger that is fitted to the fork block body 310 within a hole 312 extending through an upper portion of the fork block body 310 to the cavity in which the movable fork member 320 is disposed. The locking mechanism 360 also includes a spring biasing the plunger downwardly toward the cavity and hence, toward the movable fork member 320. The movable fork member 320 has locking holes 322 (see FIG. 9) in an upper portion thereof. The locking holes 322 are spaced from one another along the length of the movable fork member 320 and are each movable into alignment with the hole 312 in the upper portion of the fork block body 310. The locking handle 500 is connected to the locking mechanism 360 such that the locking handle 500 can move the plunger of the locking mechanism 360 in a direction opposite to that in which the plunger is biased, i.e., upwardly. Specifically, when the locking handle 500 is pushed, the locking mechanism 360 is pulled up out of a respective one of the locking holes 322 of the movable fork member 320 so that the movable fork member 320 is released (unlocked). When the locking handle 500 is free, the locking mechanism 360 can lock the movable fork member 320 in place.

The use and operation of the tray carrier 1000 according to the present invention will now be described with reference to FIGS. 2, 4, 9, and 10.

First, the tray carrier 1000 is placed over a stack of trays 700 so that the cover 600 rests on the uppermost one of the trays 700. At this time, the handles 400 are in their have been pulled out (FIG. 10) so that the movable fork members 320 are in retracted positions at which the prongs 330 are disposed within the fork block bodies 310, respectively. Also, at this time, the width of the passageway defined between the fixed fork block body 310 and the movable fork member 320 is greater than the thickness of the belt 220 that extends therethrough. Therefore, the belts 220 are free to move through the fork blocks 300. Also, the locking devices 360 lock the movable fork members 320 in place relative to the fixed block bodies 310. Then, the tray carrier 1000 is pushed down onto the stack of trays 770. As a result, the belts 220 are unwound from the belt drums 200 and surround the stack of trays 700, as shown in FIG. 4. At this time, the tension exerted on the belts 220 by the spiral springs 240 keeps the belts 220 tight against the stack of trays 700.

Next, as denoted by the arrows in FIG. 10, the locking handles 500 are pressed, and the fork block handles 400 are pushed while the locking handles 500 are held down. Accordingly, the movable fork members 320 are moved forward such that the prongs 330 are inserted into the space constituted by the open bottom end of the frame 100 and hence, under the stack of trays 700 as shown in FIG. 9. Also, the width of the passageway between the fixed fork body 310 and the movable fork member 320 of each of the fork blocks becomes less than the thickness of the belts 320. Therefore, the belts 220 are pinched between the movable members 320 and fixed fork block bodies 310 of the fork blocks 300. Then, the locking handles 500 are released so that the plungers of the locking mechanisms 360 are received in the locking holes 322 that are located towards the back of the movable fork members 320, respectively. Thus, the prongs 330 are locked in place under the stack of trays 700 and the belts 220 are held in place (clamped) over the stack of trays 700. Therefore, the stack of trays 700 is fixed to the tray carrier 1000. Then, the trays 700 can be transferred by an operator or by machine via the handle or handles 130 and 160 while protected by the frame 100 and the cover 600.

Once the trays are delivered to their desired destination, the tray carrier 1000 is set down. Then, as denoted by the arrows in FIG. 9, the locking handles 500 are pressed down and the fork block handles 400 are pulled out. Thus, the tray carrier 1000 assumes the stay represented in FIG. 10. In this state, the tray carrier 1000 is removed from the stack of trays 700, i.e., the tray carrier 100 is lifted off of the stack of trays 700. During this operation, the belts 220 are wound back onto the belt drums by the spiral springs 240.

According to the tray carrier 1000 of the present invention as described above, the stack of trays can be bundled/unbundled by manipulating the handles 130, 160 of the frame 100, the locking handles 500, and the fork block handles 400. All of these handles can be manipulated using simple mechanical motions. Thus, the tray carrier 1000 can be easily used in and operated by automated handling and transport equipment.

In addition, the handles 130 and 160, and especially the handle 130, make it easy to manually handle and move the tray carrier 1000 even when the tray carrier 1000 is loaded with a stack of trays.

Also, the tray carrier 1000 of the present invention does not provide a source of impurities such as dust. Therefore, the tray carrier 1000 can be used in environments in which semiconductor devices are manufactured.

In addition, the tray carrier 1000 of the present invention can bundle various numbers of trays together and therefore, only a minimum number of the tray carriers 1000 have to be kept on hand.

Finally, although the present invention has been described in connection with the preferred embodiments thereof, it is to be understood that the scope of the present invention is not so limited. On the contrary, various modifications of and changes to the preferred embodiments will be apparent to those of ordinary skill in the art. Thus, changes to and modifications of the preferred embodiments may fall within the true spirit and scope of the invention as defined by the appended claims.

What is claimed is:

1. A tray carrier for use in handling and transporting a stack of trays, the tray carrier comprising:
a frame having an open bottom end whose width is at least about equal to that of the trays to be carried by the tray carrier;
at least one resilient belt of material mounted to the frame and spanning the open bottom end of the frame in the width-wise direction thereof, whereby when the tray carrier is set on top of a stack of trays, the belt surrounds the top and sides of the stack of trays; and
at least one pair of fork blocks mounted to the frame, the fork blocks being disposed at opposite sides of the bottom end of the frame in the width-wise direction thereof, each of the fork blocks including a fixed fork block body that is fixed to the frame, and a movable fork member comprising a prong, the movable fork member being supported by the fixed block body so as to be movable between a first position at which the prong thereof extends into the space constituting the open bottom end of the frame and a second position at which the prong is located outside said space, whereby the prongs can be inserted under and support a stack of trays when the tray carrier is set on top of the stack of trays.

2. The tray carrier of claim 1, further comprising at least one pair of belt drums mounted to the frame, the belt drums being disposed across from one another at said opposite sides of the bottom end of the frame, the belt being wound around the belt drums, and each of the belt drums including a hub to which the belt is connected, the hub being supported so as to be rotatable about an axis, and a spring connected to the hub so as to bias the hub in one direction of rotation about the axis, the springs of the belt drums biasing the hubs in opposite directions of rotation of the hubs such that the belt is tensioned by and supported between the belt drums.

3. The tray carrier of claim 2, wherein the belt drums are disposed over the fork blocks, respectively, and the fixed fork block body and the movable fork member of each of the fork blocks define a passageway therebetween in the fork block, the belt extending through the passageway in the fork block from the belt drum that is disposed over the fork block.

4. The tray carrier of claim 3, further comprising a locking mechanism by which the movable fork member of each of the fork blocks can be selectively locked in the first and second positions thereof.

5. The tray carrier of claim 4, wherein the width of the passageway between the fixed fork body and the movable fork member of each of the fork blocks is less than the thickness of the belt when the movable fork member is in the first position thereof, and the width of the passageway is greater than the thickness of the belt when the movable fork member is at the second position thereof, whereby the belt is clamped between the fixed fork body and the movable fork member in the passageway when the movable fork member is at the first position thereof, and the belt is free to slide through the passageway when the movable fork member is at the second position thereof.

6. The tray carrier of claim 5, wherein the movable fork member has two spaced-apart holes extending therein, and the locking mechanism includes a plunger that is movable into and out of the holes, respectively, when the movable fork member is in the first and second positions thereof, and a spring that biases the plunger in a direction toward the holes.

7. The tray carrier of claim 6, wherein the frame comprises a first rigid frame unit, a second rigid frame unit spaced from the first rigid frame unit, and at least one handle extending between and connecting the frame units, and further comprising a fork block handle connected to the movable fork member of each of the fork blocks and linearly movable back and forth to move the movable fork member between the first and second positions thereof, and a locking handle connected to the locking mechanism and pressable to move the plunger of the locking mechanism in a direction opposite that in which the plunger is biased by the spring.

8. The tray carrier of claim 1, further comprising a locking mechanism by which the movable fork member of each of the fork blocks can be selectively locked in the first and second positions thereof.

9. The tray carrier of claim 1, wherein the frame comprises a first rigid frame unit, a second rigid frame unit spaced from the first rigid frame unit and having the same structure as the first frame unit and at least one handle extending between and connecting the frame units.

10. The tray carrier of claim 2, wherein the frame comprises a first rigid frame unit, a second rigid frame unit spaced from the first rigid frame unit and having the same structure as the first frame unit, and at least one handle extending between and connecting the frame units, the at least one pair of belt drums comprises a respective pair of the belt drums mounted to each of the rigid frame units, the at least one pair of fork blocks comprises a respective pair of the fork blocks mounted to each of the rigid frame units, and the at least one belt comprises a respective belt wound around the pair of belt drums mounted to each of the frame units.

11. The tray carrier of claim 10, wherein the belt drums are disposed above the fork blocks, respectively, the fixed fork block body and the movable fork member of each of the fork blocks define a passageway therebetween in the fork block, and each of the belts extends through the passageway of the fork block from the belt drum disposed above the fork block.

12. The tray carrier of claim 1, further comprising a cover integrated with the at least one belt, the size of the cover being about at least as large as the bottom open end of the frame and normally occupying the space constituted by the open bottom end of the frame, whereby when the tray carrier is set on top of a stack of trays, the cover will cover the uppermost one of the trays.

13. A system for facilitating the handling and transporting of semiconductor devices, the system comprising the combination of a stock of trays that are stackable one atop the other; and a tray carrier for handling and transporting a stack of the trays, wherein the trays have pockets in upper surfaces thereof the pockets configured to accommodate semiconductor devices, and the tray carrier includes:
a frame having an open bottom end whose width is at least about equal to that of the trays,
at least one resilient belt of material mounted to the frame and spanning the open bottom end of the frame in the width-wise direction thereof, whereby when the tray carrier is set on top of a stack of the trays, the belt surrounds the top and sides of the stack of trays, and
at least one pair of fork blocks mounted to the frame, the fork blocks being disposed at opposite sides of the bottom end of the frame in the width-wise direction thereof, each of the fork blocks including a fixed fork block body that is fixed to the frame, and a movable fork member comprising a prong, the movable fork member being supported by the fixed block body so as to be movable between a first position at which the prong thereof extends into the space constituting the open bottom end of the frame and a second position at which the prong is located outside said space, whereby the prongs can be inserted under and support a stack of the trays when the tray carrier is set on top of the stack of trays.

14. The system of claim 13, wherein the tray carrier further comprises at least one pair of belt drums mounted to the frame, the belt drums being disposed across from one another at said opposite sides of the bottom end of the frame, the belt being wound around the belt drums, and each of the belt drums including a hub to which the belt is connected, the hub being supported so as to be rotatable about an axis, and a spring connected to the hub so as to bias the hub in one direction of rotation about the axis, the springs of the belt drums biasing the hubs in opposite directions of rotation of the hubs such that the belt is tensioned by and supported between the belt drums.

15. The system of claim 14, wherein the belt drums of the tray carrier are disposed over the fork blocks, respectively, and the fixed fork block body and the movable fork member of each of the fork blocks define a passageway therebetween in the fork block, the belt extending through the passageway in the fork block from the belt drum that is disposed over the fork block.

16. The system of claim 15, wherein the tray carrier further comprises a locking mechanism by which the movable fork member of each of the fork blocks can be selectively locked in the first and second positions thereof.

17. The system of claim 16, wherein the width of the passageway between the fixed fork body and the movable fork member of each of the fork blocks is less than the thickness of the belt when the movable fork member is in the first position thereof, and the width of the passageway is greater than the thickness of the belt when the movable fork member is at the second position thereof, whereby the belt is clamped between the fixed fork body and the movable fork member in the passageway when the movable fork member is at the first position thereof, and the belt is free to slide through the passageway when the movable fork member is at the second position thereof.

18. The system of claim 17, wherein the movable fork member has two spaced-apart holes extending therein, and the locking mechanism includes a plunger that is movable into and out of the holes, respectively, when the movable fork member is in the first and second positions thereof, and a spring that biases the plunger in a direction toward the holes.

19. The system of claim 18, wherein the frame of the tray carrier comprises a first rigid frame unit, a second rigid frame unit spaced from the first rigid frame unit, and at least one handle extending between and connecting the frame units, and the tray carrier further comprises a fork block handle connected to the movable fork member of each of the fork blocks and linearly movable back and forth to move the movable fork member between the first and second positions thereof, and a locking handle connected to the locking mechanism and pressable to move the plunger of the locking mechanism in a direction opposite that in which the plunger is biased by the spring.

20. The system of claim 13, wherein the tray carrier further comprises a locking mechanism by which the movable fork member of each of the fork blocks can be selectively locked in the first and second positions thereof.

21. The system of claim 13, wherein the frame of the tray carrier comprises a first rigid frame unit, a second rigid frame unit spaced from the first rigid frame unit and having the same structure as the first frame unit, and at least one handle extending between and connecting the frame units.

22. The system of claim 14, wherein the frame of the tray carrier comprises a first rigid frame unit, a second rigid frame unit spaced from the first rigid frame unit and having the same structure as the first frame unit, and at least one handle extending between and connecting the frame units, the at least one pair of belt drums comprises a respective pair of the belt drums mounted to each of the rigid frame units, the at least one pair of fork blocks comprises a respective pair of the fork blocks mounted to each of the rigid frame units, and the at least one belt comprises a respective belt wound around the pair of belt drums mounted to each of the frame units.

23. The system of claim 22, wherein the belt drums are disposed above the fork blocks, respectively, the fixed fork block body and the movable fork member of each of the fork blocks define a passageway therebetween in the fork block, and each of the belts extends through the passageway of the fork block from the belt drum disposed above the fork block.

24. The system of claim 13, further comprising a cover adapted to rest on and cover each of the trays, whereby the cover can cover the pockets of an upper most one of a stack of the trays.

25. The system of claim 24, wherein the cover is integrated with the at least one belt of the tray carrier.

26. The system of claim 24, wherein the cover and the trays are of the same material.
